(19) United States
(12) Patent Application Publication
(10) Pub. No.: US 2025/0230546 A1
(43) Pub. Date: Jul. 17, 2025

(54) SELECTIVE CONTROL OF MULTI-STATION PROCESSING CHAMBER COMPONENTS

(71) Applicant: Lam Research Corporation, Fremont, CA (US)

(72) Inventors: Douglas Walter Agnew, Portland, OR (US); Eli Jeon, Sherwood, OR (US); Daniel Boatright, Estacada, OR (US); Trung T. Le, Vancouver, WA (US); Tuan Anh Nguyen, Beaverton, OR (US); Cody Barnett, Beaverton, OR (US); Joseph R. Abel, West Linn, OR (US); Siddappa Attur, Portland, OR (US); Mani Sankaran Kartha, Bangalore (IN)

(21) Appl. No.: 18/698,276

(22) PCT Filed: Sep. 22, 2022
(86) PCT No.: PCT/US2022/076848

§ 371 Date: Apr. 3, 2024

Related U.S. Application Data
(60) Provisional application No. 63/262,201, filed on Oct. 7, 2021.

(51) Int. Cl. C23C 16/52; C23C 16/455; H01L 21/67

(52) U.S. Cl. CPC C23C 16/52; C23C 16/45536; H01L 21/67253

(57) ABSTRACT

Various embodiments herein relate to apparatuses, systems, and methods for selective control of multi-station processing chamber components. In some embodiments, a method comprises: determining for a station of a plurality of stations, a number of deposition cycles to be performed; causing a first number of deposition cycles to be performed for each of the plurality of stations by causing a first plurality of control components associated with a first station and a second plurality of control components associated with a second station to be set to a first position; and responsive to determining that the first number of deposition cycles has been completed: causing at least one component of the first plurality of control components to be changed to a second position; and causing additional deposition cycles to be performed for the second station by causing the second plurality of control components to remain in the first position.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety.

### BACKGROUND

Multi-station processing chambers may suffer from imbalances between stations of a multi-station processing chamber. For example, there may be differences in gas flow, power transferred, etc. to the different stations. Such imbalances may cause undesired differences in substrates undergoing fabrication in the different stations. For example, there may be differences in deposition thicknesses, etch depths, etc. Moreover, utilizing each station in the same way may be an inefficient use of resources. Accordingly, it is desirable to individually control components of different stations of a multi-station processing chamber.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Systems, apparatuses, and methods for selective control of multi-station processing chamber components are provided.

In some embodiments, a method for providing station-to-station deposition uniformity in multi-station processing chambers is provided, the method comprising: obtaining a target deposition thickness for a plurality of substrates each undergoing a deposition process in a corresponding plurality of stations of a multi-station processing chamber, wherein each station of the plurality of stations is operatively coupled to common components associated with the multi-station processing chamber via a plurality of control components that are individually actuated for each station; obtaining one or more parameters indicating a plurality of deposition rates, each corresponding to a station of the plurality of stations; determining for each of the plurality of stations, a number of deposition cycles to be performed in association with the corresponding station based at least in part on the one or more parameters indicating a deposition rate of the plurality of deposition rates for a corresponding station and the target deposition thickness, wherein a first number of deposition cycles corresponding to a first station of the plurality of stations is less than a second number of deposition cycles corresponding to a second station of the plurality of stations; causing the first number of deposition cycles to be performed in connection with each of the plurality of stations by causing a first plurality of control components associated with the first station and a second plurality of control components associated with the second station to each be set to a first position associated with a deposition mode of operation; and in response to determining that the first number of deposition cycles has been completed: causing further deposition cycles to be stopped in connection with the first station by causing at least one component of the first plurality of control components associated with the first station to be changed to a second position that causes the stopping of further deposition cycles; and causing additional deposition cycles to be performed in connection with the second station until the second number of deposition cycles has been completed in connection with the second station by causing the second plurality of control components associated with the second station to remain in the first position associated with the deposition mode of operation until the second number of deposition cycles has been completed and transitioning at least one control component of the second plurality of control components to the second position that causes the stopping of further deposition cycles in response to determining that the second number of deposition cycles has been completed.

In one example, the common components comprise an RF generator. In one example, the first plurality of control components comprise at least one RF switch that operatively couples the first station to the RF generator.

In one example, the common components comprise at least one gas source. In one example, the first plurality of control components comprise at least one gas flow valve that operatively couples the first station to the at least one gas source.

In one example, the plurality of deposition rates is obtained via a user interface.

In some embodiments, a method for providing station-to-station control in multi-station processing chambers is provided, the method comprising: obtaining, via a user interface: a representation of a first time point at which a first plurality of control components associated with a first station of a multi-station processing chamber and a second plurality of control components associated with a second station of the multi-station processing chamber are each to be actuated to a first position associated with a fabrication process to occur in the first station and the second station, wherein the first plurality of control components operatively couples the first station to common components associated with the multi-station processing chamber and wherein the second plurality of control components operatively couples the second station to the common components associated with the multi-station processing chamber, and a representation of a second time point at which at least one component of the first plurality of control components is to be actuated to a second position associated with stopping of the fabrication process in the first station and at which the second plurality of control components are to remain in the first position, causing, at the first time point, the first plurality of control components and the second plurality of control components to each be actuated to the first position; and causing, at the second time point, the at least one component of the first plurality of control components to be actuated to the second position such that the fabrication process is stopped in the first station while causing the second plurality of control components to remain in the first position such that the fabrication process continues in the second station.

In one example, the fabrication process is one of a deposition process, an etch process, a passivation process, or an inhibition process.

In one example, the representation of the first time point and the representation of the second time point each correspond to a different step of the fabrication process.

In one example, the user interface comprises a plurality of selectable inputs, each corresponding to a state of a control component of the first plurality of control components or the second plurality of control components at a particular step of the fabrication process.

In one example, the user interface comprises a matrix, and wherein elements of the matrix represent states of the first plurality of control components and the second plurality of control components at different steps of the fabrication process.

In one example, the common components comprise an RF generator. In one example, the first plurality of control components comprise at least one RF switch that operatively couples the first station to the RF generator.

In one example, the common components comprise at least one gas source. In one example, the first plurality of control components comprise at least one gas flow valve that operatively couples the first station to the at least one gas source.

In some embodiments, a method for providing station-to-station control in multi-station processing chambers is provided, the method comprising: identifying: a first time point at which a first plurality of control components associated with a first station of a multi-station processing chamber and a second plurality of control components associated with a second station of the multi-station processing chamber are each to be actuated to a first position associated with a fabrication process to occur in the first station and the second station, wherein the first plurality of control components operatively couples the first station to common components associated with the multi-station processing chamber and wherein the second plurality of control components operatively couples the second station to the common components associated with the multi-station processing chamber, and a second time point at which at least one component of the first plurality of control components is to be actuated to a second position associated with stopping of the fabrication process in the first station and at which the second plurality of control components are to remain in the first position, wherein the fabrication process is an etch process, a passivation process, or an inhibition process; causing, at the first time point, the first plurality of control components and the second plurality of control components to each be actuated to the first position; and causing, at the second time point, the at least one component of the first plurality of control components to be actuated to the second position such that the fabrication process is stopped in the first station while causing the second plurality of control components to remain in the first position such that the fabrication process continues in the second station.

In one example, the first time point and the second time point each correspond to a different step of the fabrication process.

In one example, the common components comprise an RF generator. In one example, the first plurality of control components comprise at least one RF switch that operatively couples the first station to the RF generator.

In one example, the common components comprise at least one gas source. In one example, the first plurality of control components comprise at least one gas flow valve that operatively couples the first station to the at least one gas source.

### BRIEF DESCRIPTION OF THE DRAWINGS

FIG. 1 shows a substrate processing apparatus for depositing or etching a film on or over a semiconductor substrate utilizing any number of processes in accordance with some embodiments.

FIG. 2 is a schematic diagram of an example multi-station processing chamber in accordance with some embodiments.

FIG. 3 is a schematic diagram that illustrates various control components associated with an example process chamber in accordance with some embodiments.

FIGS. 4A and 4B show example user interfaces that may be used for controlling individual components of stations of a multi-station processing chamber in accordance with some embodiments.

FIG. 5 shows an example process for controlling station-to-station growth across different stations in accordance with some embodiments.

FIG. 6 shows an example of a process for controlling individual components of different stations of a multi-station processing chamber using a user interface in accordance with some embodiments.

FIG. 7 shows an example of a process for controlling individual components of different stations of a multi-station process chamber during 1) an etch process; 2) a passivation process; or 3) an inhibition process in accordance with some embodiments.

FIG. 8 presents an example computer system that may be employed to implement certain embodiments described herein.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In some embodiments, control components associated with individual stations of a multi-station processing chamber may be individually actuated such that fabrication processes may be individually controlled within each station. In some embodiments, a fabrication process may be a deposition process, such as an atomic layer deposition (ALD) process, a chemical vapor deposition process (CVD), or the like. In some embodiments, a fabrication process may be an etch process. In some embodiments, a fabrication process may be a passivation process in which a surface composition of a substrate is altered (e.g., using oxidization), for example, to protect sidewalls of a feature of the substrate during a subsequent etch process. In some embodiments, a fabrication process may be an inhibition process during which growth rates are altered at different positions of a feature (e.g. a top of a feature or a bottom of a feature) during deposition.

In some embodiments, control components may be individually actuated for individual stations to provide uniformity across the different stations. For example, individual actuation of the control components may cause a deposition process to be stopped or blocked in a particular station, while the deposition process continues in other stations. By way of example, by blocking deposition in a station associated with a faster growth rate while allowing deposition to continue in other stations with slower growth rates, a more uniform deposition thickness may be achieved across substrates undergoing the deposition process in the different stations. As another example, individual actuation of the control components may cause an etch process to be stopped or blocked in a particular station while allowing the etch process to continue in other stations. By way of example, by blocking the etch process in a station with a faster etch rate while allowing the etch process to continue in other stations with slower etch rates, a more uniform etch depth may be achieved across substrates undergoing the etch process in the different stations.

In some embodiments, control components may include individual gas flow valves that operatively couple a station to a particular gas source associated with the multi-station processing chamber. For example, a gas flow valve may be associated with a particular manifold that is used to provide gas from a gas source to a particular station during a fabrication process such that, when the gas flow valve is set to an “open” or “outlet” position, the station receives gas via the manifold, and, when the gas flow valve is set to a “closed” or “divert” position, the station does not receive gas via the manifold. In some embodiments, a first gas flow valve associated with a first station and a second gas flow valve associated with a second station may operatively couple the first station and the second station to a common gas source via a common manifold. By setting the first gas flow valve to a “closed” or “divert” position while setting the second gas flow valve to an “open” or “outlet” position, the first station may be blocked from receiving gas via the manifold while the second station may receive the gas via the manifold. Accordingly, by individual control of the first gas flow valve and the second gas flow valve, the fabrication process may be stopped in the first station while occurring in the second station.

In some embodiments, the control components may include individual RF switches that operatively couple a station to an RF generator associated with the multi-station processing chamber. For example, a first RF switch associated with a first station may operatively couple the first station to the RF generator, and a second RF switch associated with a second station may operatively couple the second station to the second RF generator. By setting the first RF switch to a “disabled” state while setting the second RF switch to an “enabled” state, the first station may be blocked from receiving RF power from the RF generator while the second station may receive RF power from the RF generator. Accordingly, via individual control of the first RF switch and the second RF switch, a fabrication process may be stopped in the first station while occurring in the second station.

In some embodiments, states and/or positions of control components for individual stations of a multi-station processing chamber may be specified by a user via a user interface. In some embodiments, states and/or positions of control components may be specified for different steps of a process. For example, the user interface may include a table, array, and/or matrix, where each element indicates a state and/or position of a component at a particular step. Through use of a user interface, a user (e.g., a process engineer) may be provided highly individual control of different stations to achieve uniformity across different stations during a fabrication process.

Certain implementations may be utilized in conjunction with a number of wafer fabrication processes, such as various plasma-enhanced atomic layer deposition (ALD) processes, various plasma-enhanced chemical vapor deposition (CVD) processes, or may be utilized on-the-fly during single deposition processes. In certain implementations, an RF power generator having multiple output ports may be utilized at any signal frequency, such as at frequencies between about 300 kHz and about 60 MHz, which may include frequencies of about 400 kHz, about 1 MHz, about 2 MHz, about 13.56 MHz, and/or about 27.12 MHz. However, in other implementations, RF power generators having multiple output ports may operate at any signal frequency, which may include relatively low frequencies, such as between about 50 kHz and about 300 kHz, as well as higher signal frequencies, such as frequencies between about 60 MHz and about 100 MHz.

It should be noted that although particular implementations described herein may show and/or describe multi-station semiconductor fabrication chambers having 4 (four) process stations, implementations are intended to embrace multi-station integrated circuit fabrication chambers having or utilizing any number of process stations. Thus, in certain implementations, individual output ports of an RF power generator having multiple output ports may be assigned to a process station of a multi-station fabrication chamber having, for example, 2 process stations or 3 process stations. In other implementations individual output ports of an RF power generator having multiple output ports may be assigned to process stations of a multi-station integrated circuit fabrication chamber having a larger number of process stations, such as 5 process stations, 6 process stations, 8 process stations, 10 process stations, or any other number of process stations. Further, embodiments of the disclosure apply to chambers having only a single process station. Additionally, although particular implementations described herein may show and/or describe utilization of a single, relatively low frequency RF signal, such as a frequency of between about 300 kHz and about 2 MHz, as well as a single, relatively high-frequency RF signal, such as a frequency of between about 2 MHz and about 100 MHz, the disclosed implementations are intended to embrace the use of any number of frequencies below about 2 MHz as well as any number of frequencies above about 2 MHz.

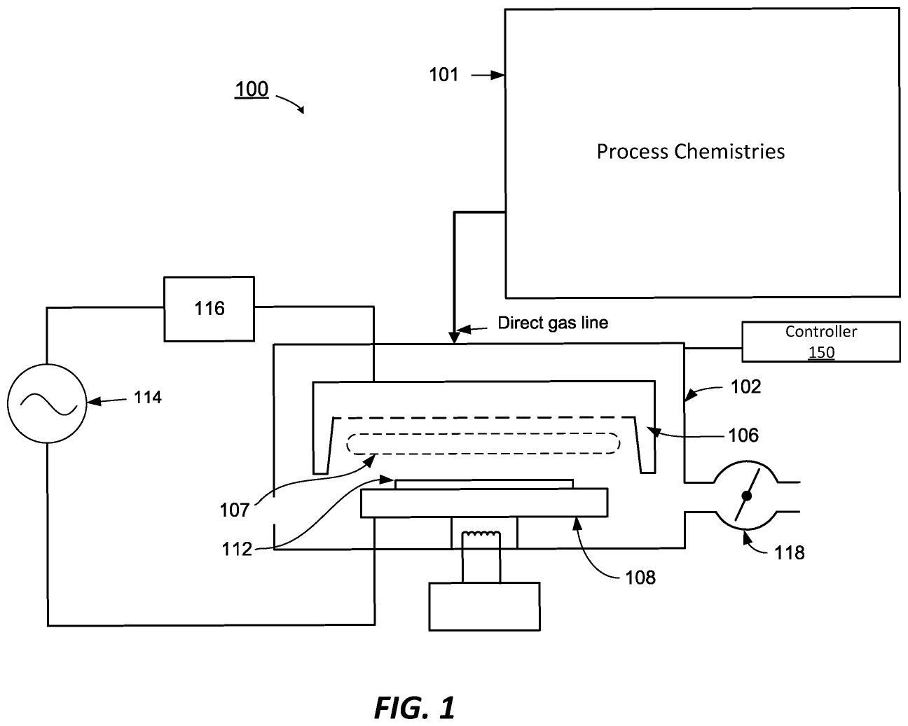

FIG. 1 shows a substrate processing apparatus 100 for depositing films on or over a semiconductor substrate utilizing any number of processes, according to various implementations. Processing apparatus 100 of FIG. 1 may employ a single process station 102 of a process chamber with a single substrate holder 108 (e.g., a pedestal) in an interior volume, which may be maintained under vacuum by vacuum pump 118. Showerhead 106 and gas delivery system 101, which may be fluidically coupled to the process chamber, may permit the delivery of film precursors, for example, as well as carrier and/or purge and/or process gases, secondary reactants, etc. Equipment utilized in the generation of plasma within the process chamber is also shown in FIG. 1. The apparatus schematically illustrated in FIG. 1 may be adapted for performing, in particular, plasma-enhanced CVD.

In some embodiments, gas delivery system 101 may include various components for performing process chemistries, such as a mixing vessel for blending and/or conditioning process gases for delivery to showerhead 106. Particular reactants may be stored in liquid form prior to vaporization and subsequent delivery to process station 102 of a process chamber. Gas delivery system may include components for vaporizing liquid reactant. In some implementations, a liquid flow controller may be provided for controlling a mass flow of liquid for vaporization and delivery to process station 102.

Showerhead 106 may operate to distribute process gases and/or reactants (e.g., film precursors) toward substrate 112 at the process station, the flow of which may be controlled by one or more valves upstream from the showerhead. In the implementation depicted in FIG. 1, substrate 112 is depicted as located beneath showerhead 106, and is shown resting on a single substrate holder 108. Showerhead 106 may include any suitable shape, and may include any suitable number and arrangement of ports for distributing process gases to substrate 112. In some implementations involving 2 or more stations, gas delivery system 101 includes valves or other flow control structures upstream from the showerhead, which can independently control the flow of process gases and/or reactants to each station so as to permit gas flow to one station while prohibiting gas flow to a second station. Furthermore, gas delivery system 101 may be configured to independently control process gases and/or reactants delivered to each station in a multi-station apparatus such that the gas composition provided to different stations is different; e.g., the partial pressure of a gas component may vary between stations at the same time.

In the implementation of FIG. 1, gas volume 107 is depicted as being located beneath showerhead 106. In some implementations, single substrate holder 108 may be raised or lowered to expose substrate 112 to gas volume 107 and/or to vary the size of gas volume 107. Optionally, single substrate holder 108 may be lowered and/or raised during portions of the deposition process to modulate process pressure, reactant concentration, etc., within gas volume 107. Showerhead 106 and single substrate holder 108 are depicted as being electrically coupled to RF signal generator 114 and matching network 116 for coupling power to a plasma generator. Thus, showerhead 106 may function as an electrode for coupling radio frequency power into process station 102. In some implementations, the plasma energy is controlled (e.g., via a system controller having appropriate machine-readable instructions and/or control logic) by controlling one or more of a process station pressure, a gas concentration, power output of an RF signal generator, and so forth. For example, RF signal generator 114 and matching network 116 may be operated at any suitable RF power level, which may operate to form plasma having a desired composition of radical species. In addition, RF signal generator 114 may provide RF power having more than one frequency component, such as a low-frequency component (e.g., less than about 2 MHz) as well as a high frequency component (e.g., greater than about 2 MHz).

In some implementations, plasma ignition and maintenance conditions are controlled with appropriate hardware and/or appropriate machine-readable instructions in a system controller which may provide control instructions via a sequence of input/output control instructions. In one example, the instructions for bringing about ignition or maintaining a plasma are provided in the form of a plasma activation portion of a process recipe. In some cases, process recipes may be sequentially arranged, so that at least some instructions for the process can be executed concurrently. In some implementations, instructions for setting one or more plasma parameters may be included in a recipe preceding a plasma ignition process. For example, a first recipe may include instructions for setting a flow rate of an inert (e.g., helium) and/or a reactant gas, instructions for setting a plasma generator to a power set point and time delay instructions for the first recipe. A second, subsequent recipe may include instructions for enabling the plasma generator and time delay instructions for the second recipe. A third recipe may include instructions for disabling the plasma generator and time delay instructions for the third recipe. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example.

In some embodiments, instructions for a controller 150 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., the first precursor), instructions for setting a flow rate of a carrier gas (such as argon), instructions for setting a first RF power level, and time delay instructions for the first recipe phase. A second, subsequent recipe phase may include instructions for modulating or stopping a flow rate of an inert and/or a reactant gas, instructions for modulating a flow rate of a carrier or purge gas, instructions for setting a second RF power level, and time delay instructions for the second recipe phase. A third recipe phase may include instructions for modulating a flow rate of a second reactant gas, instructions for modulating the duration of flow of the second reactant gas, instructions for modulating the flow rate of a carrier or purge gas, instructions for setting a third RF power level, and time delay instructions for the third recipe phase. A fourth, subsequent recipe phase may include instructions for modulating or stopping a flow rate of an inert and/or a reactant gas, and instructions for modulating a flow rate of a carrier or purge gas, instructions for setting a fourth RF power level, and time delay instructions for the fourth recipe phase. It will be appreciated that these recipe phases may be further subdivided and/or iterated in any suitable way within the scope of the disclosed embodiments.

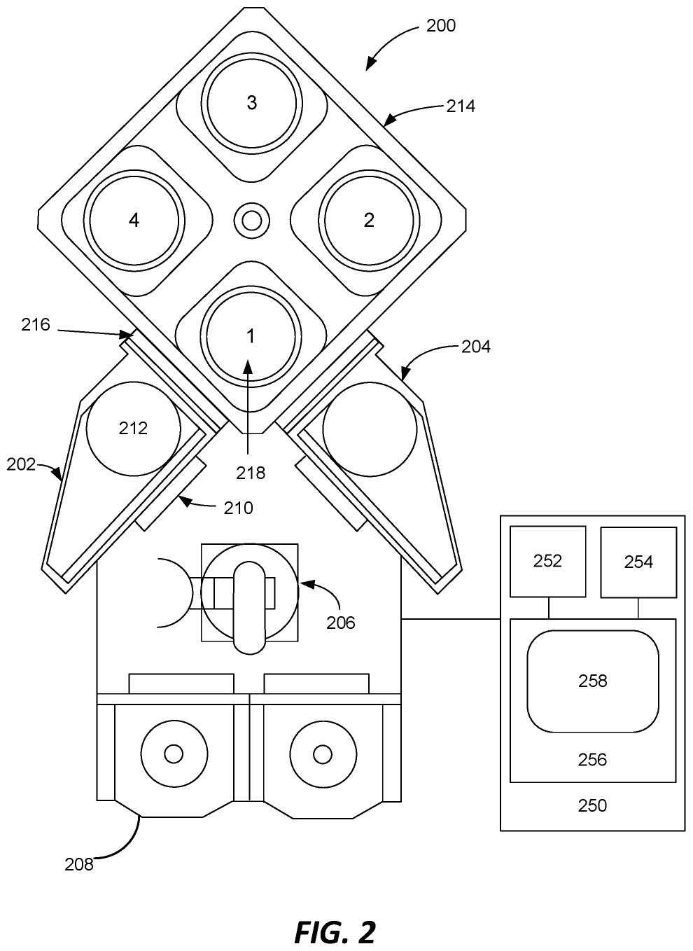

As described above, one or more process stations may be included in a multi-station processing tool. FIG. 2 shows a schematic view of an embodiment of a multi-station processing tool 200 with an inbound load lock 202 and an outbound load lock 204, either or both of which may include a remote plasma source. A robot 206 at atmospheric pressure is configured to move wafers from a cassette loaded through a pod 208 into inbound load lock 202 via an atmospheric port 210. A wafer is placed by the robot 206 on a substrate holder 212 in the inbound load lock 202, the atmospheric port 210 is closed, and the load lock is pumped down. Where the inbound load lock 202 includes a remote plasma source, the wafer may be exposed to a remote plasma treatment in the load lock prior to being introduced into a processing chamber 214. Further, the wafer also may be heated in the inbound load lock 202 as well, for example, to remove moisture and adsorbed gases. Next, a chamber transport port 216 to processing chamber 214 is opened, and another robot (not shown) places the wafer into the reactor on a substrate holder of a first station shown in the reactor for processing. While the embodiment depicted in FIG. 2 includes load locks, it will be appreciated that, in some embodiments, direct entry of a wafer into a process station may be provided.

The depicted processing chamber 214 includes four process stations, numbered from 1 to 4 in the embodiment shown in FIG. 2. Each station has a heated substrate holder (shown at 218 for station 1), and gas line inlets. It will be appreciated that in some embodiments, each process station may have different or multiple purposes. For example, in some embodiments, a process station may be switchable between an ALD and plasma-enhanced ALD process mode. Additionally or alternatively, in some embodiments, processing chamber 214 may include one or more matched pairs of ALD and plasma-enhanced ALD process stations. While the depicted processing chamber 214 includes four stations, it will be understood that a processing chamber according to the present disclosure may have any suitable number of stations. For example, in some embodiments, a processing chamber may have five or more stations, while in other embodiments a processing chamber may have three or fewer stations.

It should be understood that the various references to RF power settings of the present disclosure are generally intended, unless otherwise indicated, to refer to the RF power setting per wafer. In embodiments involving multiple process stations in a multi-station processing tool, one or more RF power sources may be provided that serve multiple process stations (e.g., simultaneously and/or sequentially). In embodiments in which a single RF power source serves multiple process stations, the per-wafer power setting of the RF power source may be multiplied by the number of process stations being simultaneously provided with plasma at a desired power level. In other words, when the present disclosure describes an RF power setting of 300 watts, it should be understood that the RF power setting reflects a per-wafer value of 300 watts and that, in multi-station processing tools, the actual RF power setting of the RF power source may be the per-wafer power setting multiplied by the number of stations.

Multi-station processing tool 200 may include a wafer handling system for transferring wafers within processing chamber 214. In some embodiments, the wafer handling system may transfer wafers between various process stations and/or between a process station and a load lock. It will be appreciated that any suitable wafer handling system may be employed. Non-limiting examples include wafer carousels and wafer handling robots. FIG. 2 also depicts an embodiment of a system controller 250 employed to control process conditions and hardware states of multi-station processing tool 200. System controller 250 may include one or more memory devices 256, one or more mass storage devices 254, and one or more processors 252. Processor 252 may include a CPU or computer, analog, and/or digital input/output connections, stepper motor controller boards, etc.

In some embodiments, system controller 250 controls all of the activities of multi-station processing tool 200. System controller 250 executes system control software 258 stored in mass storage device 254, loaded into memory device 256, and executed on processor 252. Alternatively, the control logic may be hard coded in the system controller 250. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 558 may include instructions for controlling the timing, mixture of gases, gas flow rates, chamber and/or station pressure, chamber and/or station temperature, wafer temperature, target power levels, RF power levels, substrate holder, chuck and/or susceptor position, and other parameters of a particular process performed by multi-station processing tool 200. System control software 258 may be configured in any suitable way. For example, various process tool component subroutines or control objects may be written to control operation of the process tool components used to carry out various process tool processes. System control software 258 may be coded in any suitable computer readable programming language.

In some embodiments, system control software 258 may include input/output control (IOC) sequencing instructions for controlling the various parameters described above. Other computer software and/or programs stored on mass storage device 254 and/or memory device 256 associated with system controller 250 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto substrate holder 218 and to control the spacing between the substrate and other parts of multi-station processing tool 200.

A process gas control program may include code for controlling gas composition (e.g., iodine-containing silicon precursor gases, and nitrogen-containing gases, carrier gases and purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 250. The user interface may include a display screen, graphical software displays of the apparatus and/or process conditions, and user input devices such as pointing devices, keyboards, touch screens, microphones, etc.

In some embodiments, parameters adjusted by system controller 250 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 250 from various process tool sensors. The signals for controlling the process may be output on the analog and digital output connections of multi-station processing tool 200. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 250 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 250 will typically include one or more memory devices 256 and one or more processors configured to execute the instructions so that the apparatus will perform a method in accordance with disclosed embodiments. Machine-readable media containing instructions for controlling process operations in accordance with disclosed embodiments may be coupled to the system controller 250.

In some implementations, the system controller 250 is part of a system, which may be part of the above-described examples. Such systems can include semiconductor processing equipment, including a processing tool or tools, chamber or chambers, a platform or platforms for processing, and/or specific processing components (a wafer holder, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 250, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 250 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 250 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 250, in some implementations, may be a part of or coupled to a computer that is integrated with, coupled to the system, otherwise networked to the system, or a combination thereof. For example, the system controller 250 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 250 receives instructions in the form of data, which specify parameters for each of the processing steps to be performed during one or more operations. It should be understood that the parameters may be specific to the type of process to be performed and the type of tool that the system controller 250 is configured to interface with or control. Thus as described above, the system controller 250 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an PEALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 250 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

It should be noted that FIG. 2 depicts merely one example of a multi-station processing chamber that may be used in some embodiments of the techniques, systems, and methods described herein. In some implementations, a multi-station processing chamber may include multiple chambers or reactors (e.g., two, four, six, eight, etc.), where the multiple chambers or reactors are modular in nature and are clustered. For example, the multiple chambers or reactors may be clustered around one or more shared components, such as one or more wafer handling systems, a system controller, etc. The multiple chambers or reactors may be under a common vacuum environment. In some embodiments, the vacuum environment, and the multiple modules it encloses, as well as the shared wafer handling resources, is collectively referred to as “a cluster tool.”

In some embodiments, an individual station of a multi-station processing chamber is operatively coupled to components common to all of the stations of the multi-station processing chamber. Such components may include one or more manifolds that are each coupled to a gas source, an RF generator, or the like. In some embodiments, a station may be operatively coupled to a common component via an individually controllable component. For example, a station may be operatively coupled to a manifold via a gas valve. More particularly, a first station may be operatively coupled to the manifold via a first gas valve, and a second station may be operatively coupled to the manifold via a second gas valve, where the first gas valve and the second gas valve may be independently controlled and/or actuated. In this example, occurrence of a fabrication process in a particular station may require that the station receive gas flow via the manifold, and therefore, that the corresponding valve be set to an open position. In one example, during a first time period, the first gas valve and the second gas valve may both be set to an open or outlet position such that the first station and the second station both receive gas flow via the manifold. Continuing with this example, during a second time period, the first gas valve may be set to a closed or divert position while the second gas valve may be set to an open or outlet position such that the first station does not receive gas flow via the manifold and such that the second station does receive gas flow via the manifold. As another example, a station may be operatively coupled to an RF generator via an RF switch. In this example, occurrence of a fabrication process in a particular station may require that the station receive RF power from the RF generator, and therefore, that the corresponding RF switch is set to an enabled position. More particularly, a first station may be operatively coupled to the RF generator via a first RF switch, and a second station may be operatively coupled to the RF generator via a second RF switch. In one example, during a first time period, the first RF switch and the second RF switch may both be set to an enabled state, such that both the first station and the second station receive RF power from the RF generator. Continuing with this example, during a second time period, the first RF switch may be set to a disabled state while the second RF switch is set to an enabled state, such that the first station does not receive RF power from the RF generator and such that the second station does receive RF power from the RF generator.

In some embodiments, a multi-station processing chamber is associated with one or more manifolds, where each manifold may be coupled to a different gas source. Different manifolds may be used in association with different fabrication processes. For example, a first manifold may be used for gas flow during a deposition process. As another example, a second manifold may be used for gas flow during an etch process and/or during an inhibition process. As used herein, an inhibition process refers to adjusting growth rates within features during, for example, an ALD process. For example, an inhibition process may be used to prevent growth from occurring at a top of a feature while allowing growth to occur at a bottom of a feature. As yet another example, a third manifold may be used during oxidation steps and a fourth manifold may be used during reduction steps. In a more particular example, the third manifold and/or the fourth manifold may be used during a passivation process. As used herein, a passivation process may be used to change the surface composition of a film or substrate, for example, the prevent etching of sidewalls of a feature.

In some embodiments, corresponding valves may have a naming convention that indicates that the corresponding valves may operatively couple a particular manifold to different stations. For example, a valve X01 may operatively couple station X to a particular manifold. As a more particular example, in some embodiments, a multi-station processing chamber that includes four stations may include valves x101, x201, x301, and x401, where valve x101 operatively couples station 1 to the manifold, valve x201 operatively couples station 2 to the manifold, and so on.

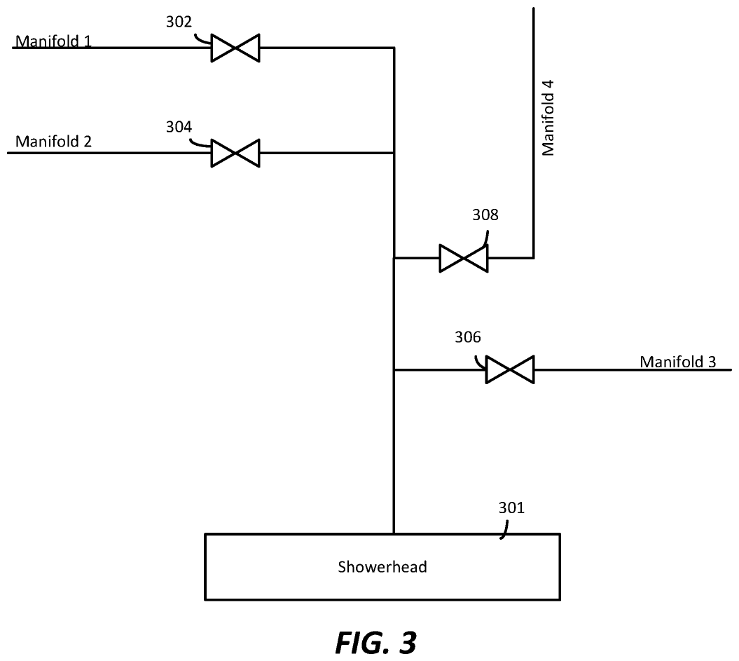

FIG. 3 shows a schematic diagram of an example coupling of various manifolds to a single station of a multi-station processing chamber in accordance with some embodiments. As illustrated, multiple manifolds are coupled to a showerhead 301. For example, Manifold 1 is operatively coupled to showerhead 301 via a valve 302, Manifold 2 is operatively coupled to showerhead 301 via a valve 304, Manifold 3 is operatively coupled to showerhead 301 via a valve 306, and Manifold 4 is operatively coupled to showerhead 301 via a valve 308. As described below, in some embodiments, each of valves 302, 304, 306, and 308 may be individually actuated separately from the corresponding valves associated with other stations of the multi-station processing chamber. In some embodiments, each manifold may be operatively coupled to a different gas source. For example, Manifold 1 may be used to provide a first gas via a first gas source to the station, and Manifold 2 may be used to provide a second gas via a second gas source to the station. In some embodiments, different manifolds may be used in connection with different fabrication processes. Additionally or alternatively, in some embodiments, multiple manifolds may be during performance of a single fabrication process. Although four manifolds are depicted in FIG. 3, it should be understood that a station may be operatively coupled to any suitable number of manifolds.

In some embodiments, steps of a process at which individual control components of individual stations of a multi-station processing chamber are to be actuated to certain positions may be specified by a user via a user interface. Accordingly, time points at which individual control components of individual stations of a multi-station processing chamber are to be actuated to certain positions may be identified via data obtained via the user interface. For example, a user interface may include indications of a set of parameters, where a value of each parameter of the set of parameters may be individually set and/or modified at different steps of a process. Examples of parameters include particular valves for a particular station (e.g., a valve corresponding to Station 1 and Manifold 1, a valve corresponding to Station 2 and Manifold 1, a valve corresponding to Station 1 and Manifold 2, a valve corresponding to Station 2 and Manifold 2, etc.), RF switches for particular stations (e.g., an RF switch for Station 1, an RF switch for Station 2, etc.).

In some embodiments, a user interface for indicating positions and/or states of control components at different steps of a process may include a table, array, and/or matrix, where each element corresponds to a position and/or state of a particular control component at a particular step of a process. For example, rows of a table, array, and/or matrix may correspond to different parameters (e.g., different control components). Continuing with this example, columns of the table, array, and/or matrix may correspond to different steps of the process. In some embodiments, a value of a particular control component may be changed at a particular step of a process by modifying the corresponding element in the table, array, and/or matrix presented in the user interface. For example, in some embodiments, elements of the table, array, and/or matrix may be selectable within the user interface. Continuing with this example, in some embodiments, selection of a particular element may allow a user to alter a value of a parameter. In one example, selection of a particular element may cause the state of the parameter (e.g., control component) to toggle to an alternative value in instances in which the parameter may take one of two values. By way of example, a value of a parameter corresponding to an RF switch may toggle from “enabled” to “disabled,” or vice versa. In another example, selection of a particular element may allow a user to select a different value of the parameter, for example, by causing a drop down menu of other possible values to be presented to the user for selection. By way of example, selection of an element corresponding to a control component that controls gas flow rate may cause a drop down menu that indicates potential rates to be presented, where the user can select, via the drop down menu. In some embodiments, parameters which may not be altered at particular steps of a process may be indicated, for example, by graying out the corresponding elements in the table, array, and/or matrix, by causing the corresponding elements to not be selectable, or the like.

It should be noted that, in some embodiments, a user interface may be presented on a user device, such as a desktop computer, a laptop computer, a tablet computer, or the like. Information obtained via the user interface may then be communicated (e.g., transmitted) to a controller associated with a multi-station processing chamber and/or to one or more controllers associated with individual stations of the multi-station processing chamber. The controller(s) may then act on information obtained via the user interface, for example, by actuating particular control components to certain positions or states indicated at particular time points as indicated via the user interface.

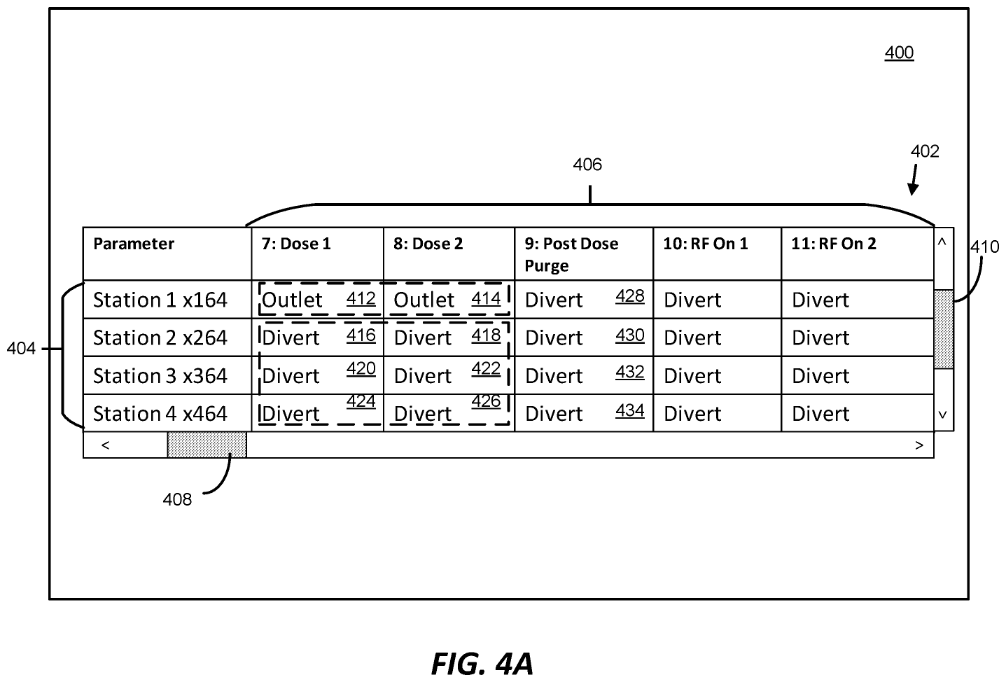

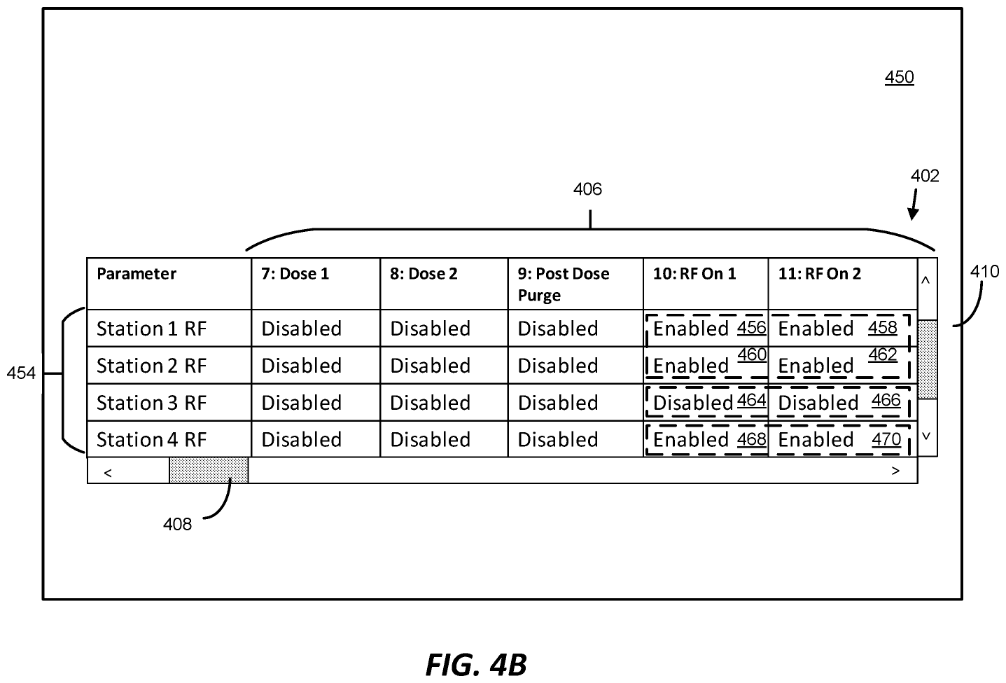

FIG. 4A shows an example user interface 400 for altering positions and/or states of valves of different stations of a multi-station processing chamber in accordance with some embodiments. As illustrated, user interface 400 includes a table 402. Table 402 includes rows 404 and columns 406. Each of rows 404 corresponds to a different parameter, or control component. In the example of FIG. 4A, each of rows 404 corresponds to a particular gas flow valve, in particular, Station 1 valve x164, Station 2 valve x264, Station 3 valve x364, and Station 4 valve x464. Each of columns 406 corresponds to a different step of a process, such as “Dose 1,” “Dose 2,” “Post Dose Purge,” “RF On 1,” and “RF On 2.” In some embodiments, rows may be scrolled using slider 410, for example, to view rows above and/or below those shown in user interface 400. In some embodiments, columns may be scrolled using slider 408, for example, to view process steps before and/or after those shown in user interface 400.

As illustrated in FIG. 4A, each element of table 402 corresponds to a value of the parameter indicated in the corresponding row at the step indicated in the corresponding column. For example, element 412 indicates a state and/or position of Station 1 valve x164 at Step 7. As illustrated in FIG. 4A by elements 412 and 414, the state and/or position of Station 1 valve x164 has been set to “outlet” at Steps 7 and 8. Conversely, as indicated by elements 416-426, the states and/or positions of Station 2 valve x264, Station 3 valve x364, and Station 4 valve x464 have been sent to “divert” at Steps 7 and 8. Accordingly, because valves x164, x264, x364, and x464 correspond to the same manifold (and therefore, the same common gas source of the multi-station processing chamber) but for different stations, when the process represented in user interface 400 is performed, at Steps 7 and 8, gas may flow to Station 1 via the manifold corresponding to valve x164, whereas gas flow may be blocked to Stations 2-4 via the same manifold.

It should be noted that states and/or positions of valves x164, x264, x364, and x464 may not be permitted to be changed by a user at particular steps of a process, such as at Step 9, corresponding to “Post Dose Purge.” In some embodiments, the corresponding elements (e.g., elements 428-434) may not be selectable within user interface 400. In some embodiments, the corresponding elements (e.g., elements 428-434) may be grayed out.

FIG. 4B shows an example user interface 450 for altering states of RF switches of different stations of a multi-station processing chamber in accordance with some embodiments. It should be noted that user interface 450 illustrates table 402 (e.g., as shown in FIG. 4A) with different rows 454 shown. In particular, rows 454 indicate parameters corresponding to the control components of RF switches for Station 1, Station 2, Station 3, and Station 4, respectively. In other words, rows 454 may indicate rows above or below rows 404 shown in and described above in connection with FIG. 4A.

As illustrated, the state of each RF switch (e.g., the RF switch for each station that couples the station to a common RF generator associated with the multi-station processing chamber) may be toggled, for example, via any of elements 456-470. For example, the state of an RF switch for Station 1 may be toggled (e.g., between enabled and disabled) for Step 10 and Step 11 via elements 456 and 458, respectively. As another example, the state of an RF switch for Station 3 may be toggled (e.g., between enabled and disabled) for Step 10 and Step 11 via elements 464 and 466, respectively. As illustrated in FIG. 4B, RF switches for different stations may be set to different states for a particular step of a process. In the example shown in FIG. 4B, the RF switches for Stations 1, 2, and 4 are enabled at Step 10 and Step 11, whereas the RF switch for Station 3 is disabled at Steps 10 and Step 11. Accordingly, in the example shown in FIG. 4B, Stations 1, 2, and 4 are operatively coupled to the RF generator at Step 10 and Step 11 (and therefore, receive RF power from the RF generator), whereas Station 3 is not operatively coupled to the RF generator at Step 10 and Step 11 (and therefore, does not receive RF power from the RF generator).

In some embodiments, a number of deposition cycles performed during a deposition process (e.g., during an ALD process) may be altered on a station-by-station basis. For example, a first number of deposition cycles may be performed on a group of stations of a multi-station processing chamber, and, subsequently, a second number of deposition cycles may be performed on a subset of the group of stations. As a more particular example, performance of the second number of deposition cycles may be blocked on one or more stations of the multi-station processing chamber based at least in part on a deposition growth rate associated with the one or more stations. In one example, additional deposition cycles may not be performed on one or more stations that have a relatively higher deposition growth rate relative to a subset of stations that have a relatively lower deposition growth rate.

In some embodiments, the number of deposition cycles to be performed at each station of a multi-station processing chamber may be determined based on a deposition growth rate associated with each station. In some embodiments, the deposition growth rate may be specified for each station by a user prior to execution of a process on the multi-station process chamber, for example, via a user interface. For example, the user interfaces shown in FIGS. 4A and 4B may include rows corresponding to “Deposition Growth Rate” for each station. In some embodiments, the number of deposition cycles to be performed at each station may be determined based at least in part on in situ monitoring. For example, additional deposition cycles may be blocked from being performed on a particular station in response to receiving in situ data that indicates a faster than expected deposition growth rate.

In some embodiments, whether a particular deposition cycles is performed at a particular station may be controlled by actuating particular control components associated with the station. The control components may include gas flow valves (e.g., a gas flow valve that controls whether gas flows to the station through a particular manifold associated with flowing gas to the station during a deposition cycle) and/or RF switches. For example, a deposition cycle may be blocked from being performed at a particular station by actuating a gas flow valve to a “closed” or “divert” position during the deposition cycle, thereby preventing gas from flowing to the station during the deposition cycle. As another example, a deposition cycle may be blocked from being performed at a particular station by setting an RF switch associated with the station to a “disabled” state during the deposition cycle, thereby preventing RF power from being provided to the station during the deposition cycle. In some embodiments, the state and/or the position of each control component may be specified for particular steps of a process via a user interface, as shown in and described above in connection with FIGS. 4A and 4B.

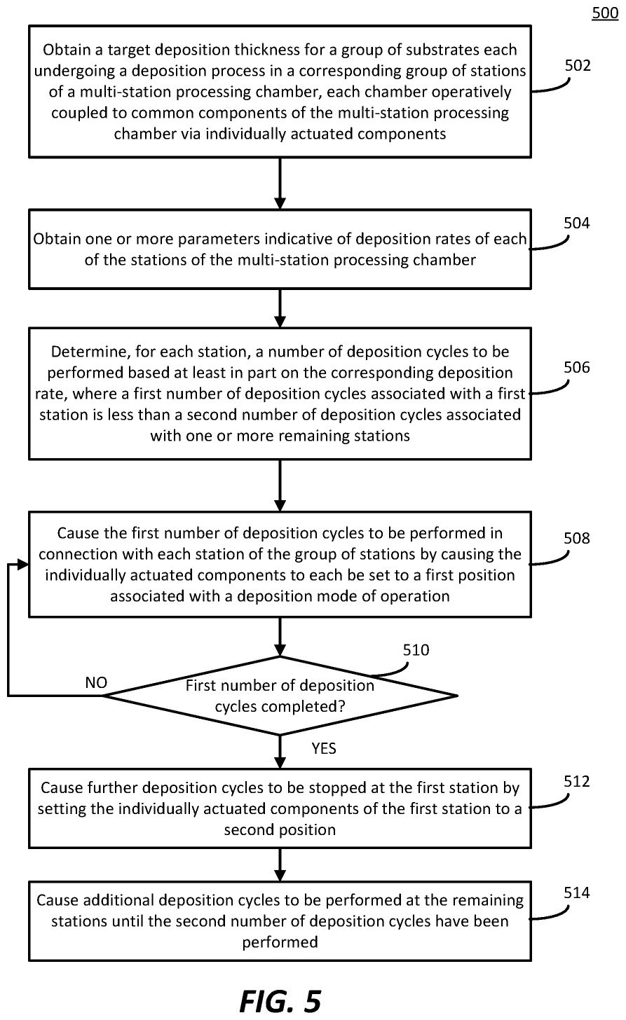

FIG. 5 shows an example of a process 500 for controlling a number of deposition cycles performed on a station-by-station basis by actuating control components at each station in accordance with some embodiments. In some embodiments, blocks of process 500 may be executed by a controller associated with a multi-station processing chamber. In some embodiments, blocks of process 500 may be performed in an order other than what is shown in FIG. 5. In some embodiments, two or more blocks of process 500 may be performed substantially in parallel. In some embodiments, one or more blocks of process 500 may be omitted.

Process 500 can begin at 502 by obtaining a target deposition thickness for a group of substrates each undergoing a deposition process in a corresponding group of stations of a multi-station processing chamber, each chamber operatively coupled to common components of the multi-station processing chamber via individually actuated components. In some embodiments, the target deposition thickness for each substrate of the group of substrates may be the same. In some embodiments, the common components of the multi-station processing chamber may include one or more common gas sources, a common RF generator, etc.

At 504, process 500 may obtain one or more parameters indicative of deposition rates of each of the stations of the multi-station processing chamber. For a particular station, the deposition rate may indicate a growth (e.g., in Angstroms) for one deposition cycle at the station. Note that the deposition rates may be different for each station of the multi-station processing chamber, which may be indicative of inter-station differences. In some embodiments, the deposition rates for each station may be obtained via a user interface. In some embodiments, the deposition rates for each station may be determined by a controller, for example, based on in situ or ex situ data obtained during prior-performed deposition processes.

At 506, process 500 may determine, for each station, a number of deposition cycles to be performed based at least in part on the corresponding deposition rate. For example, in some embodiments, for a particular station, the number of deposition cycles may be determined by dividing the target deposition thickness obtained at block 502 by the deposition rate for the station obtained at block 504. In some embodiments, the number of deposition cycles may be the quotient of the target deposition thickness and the deposition rate rounded to the nearest integer, rounded up, or rounded down. In some embodiments, a first number of deposition cycles associated with a first station may be less than a second number of deposition cycles associated with one or more remaining station. For example, the number of deposition cycles to be performed at the first station may be 1200, whereas the number of deposition cycles to be performed at a second station may be 1250. It should be noted that, although process 500 generally describes deposition cycles performed at two stations of a multi-station processing chamber, the techniques described herein may be expanded to any suitable number (e.g., 4, 6, 8, 10, etc.) stations. In some embodiments, each station may perform a different number of deposition cycles. In some embodiments, two or more stations may perform the same number of deposition cycles.

At 508, process 500 can cause the first number of deposition cycles to be performed in connection with each station of the group of stations by causing the individually actuated components to each be set to a first position associated with a deposition mode of operation. For example, process 500 can cause a gas flow valve associated with each station to be set to an “open” or “outlet” position during portions of the first number of deposition cycles that involve flowing gas to each station. As another example, process 500 can cause an RF switch associated with each switch to be set to an “enabled” position during portions of the first number of deposition cycles that involve providing RF power to each station.

At 510, process 500 can determine whether the first number of deposition cycles have been completed. For example, process 500 can compare a number of deposition cycles that have been completed to the first number of deposition cycles.

If, at 510, process 500 determines that the first number of deposition cycles have not been completed (“no” at 510), process 500 can loop back to block 508 and continue to cause additional deposition cycles to be performed at each station of the multi-station processing chamber until the first number of deposition cycles have been performed.

If, at 510, process 500 determines that the first number of deposition cycles have been completed (“yes” at 510), process 500 can proceed to 512 and can cause further deposition cycles to be stopped at the first station by setting at least a portion of the individually actuated components of the first station to a second position associated with blocking or stopping the deposition process in the first station. For example, in some embodiments, process 500 can cause a gas flow valve associated with the first station to be set to a “closed” or “divert” position, thereby blocking gas flow to the first station. As another example, in some embodiments, process 500 can cause an RF switch associated with the first station to be set to a “disabled” state, thereby blocking RF power from being provided to the first station.

At 514, process 500 can cause additional deposition cycles to be performed at the remaining stations other than the first station by causing the individually actuated components associated with the remaining stations to remain in the first positions associated with the deposition mode of operation until the second number of deposition cycles have been performed. For example, while gas flow and/or RF power may be blocked to the first station during performance of the additional deposition cycles, thereby preventing deposition growth on the substrate at the first station, gas flow and RF power may be provided to the remaining stations, thereby allowing for deposition growth on the substrates of the remaining stations.

It should be noted that although process 500 describes performing a second number of deposition cycles on a subset of stations, it should be understood that N deposition cycles may be performed at X stations, N′ deposition cycles may be performed at X−1 stations, N″ deposition cycles may be performed at X−2 stations, and so on, where N>N′>N″.

In some embodiments, timing information associated with when various control components associated with particular stations of a multi-station process chamber are to be actuated to different states and/or positions may be based at least in part on information obtained from a user interface. Examples of such user interfaces are shown in and described above in connection with FIGS. 4A and 4B. For example, a state and/or position of a particular control component may be specified via the user interface for each step of a process. Corresponding control components (e.g., gas flow valves) of different stations may be specified as to be set to different states and/or positions for a particular step of a process, thereby causing, for example deposition cycles, etch cycles, passivation cycles, and/or inhibition cycles to be performed and/or blocked from being performed at each station individually.

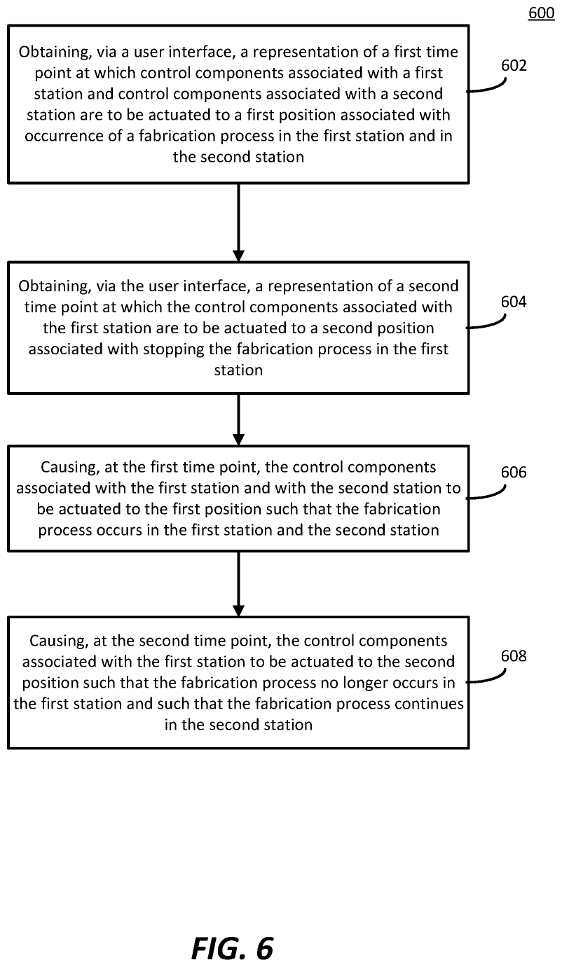

FIG. 6 shows an example of a process 600 for controlling individual components of stations of a multi-station processing chamber based on information obtained from a user interface in accordance with some embodiments. It should be noted that although process 600 describes a first station and a second station of a multi-station processing chamber, the techniques described below may be expanded to any suitable number of stations (e.g., 4, 6, 8, 10, etc.). In some embodiments, blocks of process 600 may be performed in an order other than what is shown in FIG. 6. In some embodiments, two or more blocks of process 600 may be performed substantially in parallel. In some embodiments, one or more blocks of process 600 may be omitted.

Process 600 can begin at 602 by obtaining, via a user interface, a representation of a first time point at which control components associated with a first station and control components associated with a second station are to be actuated to a first position associated with occurrence of a fabrication process in the first station and the second station. In some embodiments, the representation of the first time point may correspond to a particular step of the fabrication process (e.g., a dosing phase of a deposition cycle, or the like). In some embodiments, control components may include gas flow valves, each associated with a particular manifold coupled to a common gas source associated with the multi-station processing chamber, and/or RF switches that couple an RF generator of the multi-station processing chamber to a particular station. The fabrication process may be a deposition process, an etch process, a passivation process, and/or an inhibition process.

At 604, process 600 may obtain, via the user interface, a representation of a second time point at which the control components associated with the first station are to be actuated to a second position associated with stopping the fabrication process in the first station. The representation of the second time point may correspond to a different step of the fabrication process other than that corresponding to the representation of the first time point. For example, the representation of the second time point may correspond to an additional deposition cycle that is not to be performed at the first station. As another example, the representation of the second time point may correspond to an additional etch cycle that is not to be performed at the first station.

At 606, process 600 may cause, at the first time point, the control components associated with the first station and with the second station to be actuated to the first position such that the fabrication process occurs in both the first station and the second station. For example, process 600 may cause gas flow valves associated with a particular manifold to be set to an “open” or “outlet” position for each of the first station and the second station such that the first station and the second station each receive gas via the manifold during the fabrication process. As another example, process 600 may cause RF switches to be set to an “enabled” state for each of the first station and the second station such that the first station and the second station each receive RF power from an RF generator of the multi-station processing chamber during the fabrication process.

At 608, process 600 can cause, at the second time point, at least a portion of the control components associated with the first station to be actuated to the second position such that the fabrication process no longer occurs in the first station and such that the fabrication process continues in the second station. For example, in some embodiments, process 600 can set a gas flow valve associated with the first station to be set to a “closed” or “divert” position such that the first station no longer receives gas flow, effectively stopping the fabrication process in the first station. Continuing with this example, the gas flow valve associated with the second station may remain in the “open” or “outlet” position such that the second station continues to receive gas flow during the fabrication process. As another example, in some embodiments, process 600 can set an RF switch associated with the first station to be set to a “disabled” state such that the first station no longer receives RF power from an RF generator associated with the multi-station processing chamber, thereby effectively stopping the fabrication process in the first station. Continuing with this example, the RF switch associated with the second station may remain in the “enabled” state such that the fabrication process continues in the second station.

In some embodiments, control components associated with individual stations of a multi-station processing chamber may be individually actuated in association with an etch process, a passivation process, and/or an inhibition process. For example, different numbers of etch cycles, passivation cycles, and/or inhibition cycles may be performed in each station. As a more particular example, a different number of etch cycles may be performed in different stations to control etch depth (e.g., to achieve a more uniform etch depth) across substrates undergoing the etch process in different stations of the multi-station processing chamber. As another more particular example, a different number of passivation cycles may be performed in different stations to achieve different surface compositions for different substrates undergoing a passivation process in different stations of the multi-station processing chamber. In such an example, sidewalls of features of the different substrates may be coated differently such that sidewalls are protected during subsequent etch processes in accordance with an etch rate of each station. As another more particular example, a different number of inhibition cycles may be performed in different stations to achieve different deposition growth at different feature positions (e.g., a top portion of a feature, a bottom portion of a feature, or the like) of substrates in each of the different stations.

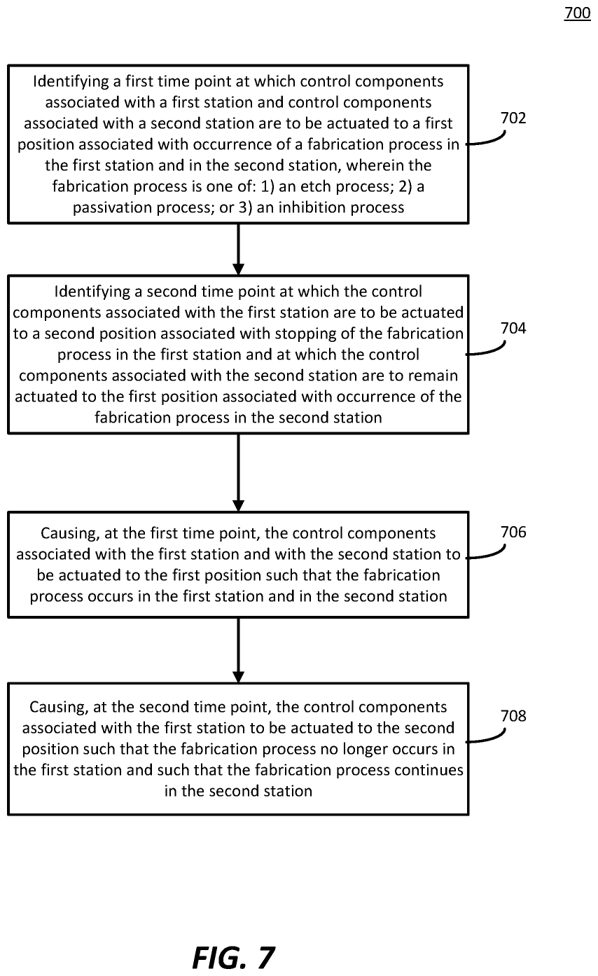

FIG. 7 shows an example of a process 700 for controlling individual components of stations of a multi-station processing chamber which may be used for different fabrication processes in accordance with some embodiments. It should be noted that although process 700 describes a first station and a second station of a multi-station processing chamber, the techniques described below may be expanded to any suitable number of stations (e.g., 4, 6, 8, 10, etc.). In some embodiments, blocks of process 700 may be performed in an order other than what is shown in FIG. 7. In some embodiments, two or more blocks of process 700 may be performed substantially in parallel. In some embodiments, one or more blocks of process 700 may be omitted.

Process 700 can begin at 702 by identifying a first time point at which control components associated with a first station and control components associated with a second station are to be actuated to a first position associated with occurrence of a fabrication process in the first station and the second station. The fabrication process may be an etch process, a passivation process, or an inhibition process. In some embodiments, the representation of the first time point may correspond to a particular step of the fabrication process. In some embodiments, control components may include gas flow valves, each associated with a particular manifold coupled to a common gas source associated with the multi-station processing chamber and/or RF switches that couple an RF generator of the multi-station processing chamber to a particular station. In some embodiments, the first time point may be identified based on information obtained via a user interface. In some embodiments, the first time point may be identified based at least in part on in situ monitoring and/or based on ex situ data obtained during a prior-performed fabrication process. For example, in situ data and/or ex situ data may indicate growth rates and/or etch rates associated with each station, which may be used to determine a number of etch cycles, passivation cycles, and/or inhibition cycles to be performed at each station.

At 704, process 700 may identify a second time point at which the control components associated with the first station are to be actuated to a second position associated with stopping the fabrication process in the first station. The second time point may correspond to a different step of the fabrication process other than that corresponding to the first time point. For example, the second time point may correspond to an additional etch cycle that is not to be performed at the first station. In some embodiments, the second time point may be identified based on information obtained via a user interface. In some embodiments, the second time point may be identified based at least in part on in situ monitoring and/or based on ex situ data obtained during a prior-performed fabrication process. For example, in situ data and/or ex situ data may indicate growth rates and/or etch rates associated with each station, which may be used to determine a number of etch cycles, passivation cycles, and/or inhibition cycles to be performed at each station.

At 706, process 700 may cause, at the first time point, the control components associated with the first station and with the second station to be actuated to the first position such that the fabrication process occurs in both the first station and the second station. For example, process 700 may cause gas flow valves associated with a particular manifold to be set to an “open” or “outlet” position for each of the first station and the second station such that the first station and the second station each receive gas via the manifold during the fabrication process. As another example, process 700 may cause RF switches to be set to an “enabled” state for each of the first station and the second station such that the first station and the second station each receive RF power from an RF generator of the multi-station processing chamber during the fabrication process.

At 708, process 700 can cause, at the second time point, at least a portion of the control components associated with the first station to be actuated to the second position such that the fabrication process no longer occurs in the first station and such that the fabrication process continues in the second station. For example, in some embodiments, process 700 can set a gas flow valve associated with the first station to be set to a “closed” or “divert” position such that the first station no longer receives gas flow, effectively stopping the fabrication process in the first station. Continuing with this example, the gas flow valve associated with the second station may remain in the “open” or “outlet” position such that the second station continues to receive gas flow during the fabrication process. As another example, in some embodiments, process 700 can set an RF switch associated with the first station to be set to a “disabled” state such that the first station no longer receives RF power from an RF generator associated with the multi-station processing chamber, thereby effectively stopping the fabrication process in the first station. Continuing with this example, the RF switch associated with the second station may remain in the “enabled” state such that the fabrication process continues in the second station.

### Context for Disclosed Computational Embodiments

Certain embodiments disclosed herein relate to computational systems for controlling components of individual stations of a multi-station processing chamber.

Many types of computing systems having any of various computer architectures may be employed as the disclosed systems for implementing algorithms as described herein. For example, the systems may include software components executing on one or more general purpose processors or specially designed processors such as Application Specific Integrated Circuits (ASICs) or programmable logic devices (e.g., Field Programmable Gate Arrays (FPGAs)). Further, the systems may be implemented on a single device or distributed across multiple devices. The functions of the computational elements may be merged into one another or further split into multiple sub-modules.

In some embodiments, code executed during generation or execution of a technique for controlling components of stations of a multi-station processing chamber on an appropriately programmed system can be embodied in the form of software elements which can be stored in a nonvolatile storage medium (such as optical disk, flash storage device, mobile hard disk, etc.), including a number of instructions for making a computer device (such as personal computers, servers, network equipment, etc.).

At one level a software element is implemented as a set of commands prepared by the programmer/developer. However, the module software that can be executed by the computer hardware is executable code committed to memory using “machine codes” selected from the specific machine language instruction set, or “native instructions,” designed into the hardware processor. The machine language instruction set, or native instruction set, is known to, and essentially built into, the hardware processor(s). This is the “language” by which the system and application software communicates with the hardware processors. Each native instruction is a discrete code that is recognized by the processing architecture and that can specify particular registers for arithmetic, addressing, or control functions; particular memory locations or offsets; and particular addressing modes used to interpret operands. More complex operations are built up by combining these simple native instructions, which are executed sequentially, or as otherwise directed by control flow instructions.

The inter-relationship between the executable software instructions and the hardware processor is structural. In other words, the instructions per se are a series of symbols or numeric values. They do not intrinsically convey any information. It is the processor, which by design was preconfigured to interpret the symbols/numeric values, which imparts meaning to the instructions.

The methods and techniques used herein may be configured to execute on a single machine at a single location, on multiple machines at a single location, or on multiple machines at multiple locations. When multiple machines are employed, the individual machines may be tailored for their particular tasks. For example, operations requiring large blocks of code and/or significant processing capacity may be implemented on large and/or stationary machines.

In addition, certain embodiments relate to tangible and/or non-transitory computer readable media or computer program products that include program instructions and/or data (including data structures) for performing various computer-implemented operations. Examples of computer-readable media include, but are not limited to, semiconductor memory devices, phase-change devices, magnetic media such as disk drives, magnetic tape, optical media such as CDs, magneto-optical media, and hardware devices that are specially configured to store and perform program instructions, such as read-only memory devices (ROM) and random access memory (RAM). The computer readable media may be directly controlled by an end user or the media may be indirectly controlled by the end user. Examples of directly controlled media include the media located at a user facility and/or media that are not shared with other entities. Examples of indirectly controlled media include media that is indirectly accessible to the user via an external network and/or via a service providing shared resources such as the “cloud.” Examples of program instructions include both machine code, such as produced by a compiler, and files containing higher level code that may be executed by the computer using an interpreter.

In various embodiments, the data or information employed in the disclosed methods and apparatus is provided in an electronic format. Such data or information may include various coefficients to be used in calculations, and the like. As used herein, data or other information provided in electronic format is available for storage on a machine and transmission between machines. Conventionally, data in electronic format is provided digitally and may be stored as bits and/or bytes in various data structures, lists, databases, etc. The data may be embodied electronically, optically, etc.

System software typically interfaces with computer hardware and associated memory. In some embodiments, the system software includes operating system software and/or firmware, as well as any middleware and drivers installed in the system. The system software provides basic non-task-specific functions of the computer. In contrast, the modules and other application software are used to accomplish specific tasks. Each native instruction for a module is stored in a memory device and is represented by a numeric value.

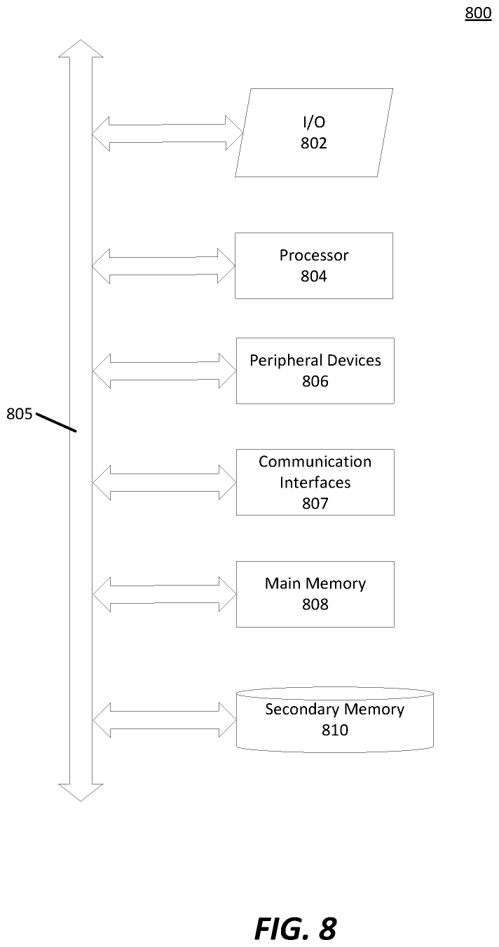

An example computer system 800 is depicted in FIG. 8. As shown, computer system 800 includes an input/output subsystem 802, which may implement an interface for interacting with human users and/or other computer systems depending upon the application. Embodiments of the disclosure may be implemented in program code on system 800 with I/O subsystem 802 used to receive input program statements and/or data from a human user (e.g., via a GUI or keyboard) and to display them back to the user. The I/O subsystem 802 may include, e.g., a keyboard, mouse, graphical user interface, touchscreen, or other interfaces for input, and, e.g., an LED or other flat screen display, or other interfaces for output.

Communication interfaces 807 can include any suitable components or circuitry used for communication using any suitable communication network (e.g., the Internet, an intranet, a wide-area network (WAN), a local-area network (LAN), a wireless network, a virtual private network (VPN), and/or any other suitable type of communication network). For example, communication interfaces 807 can include network interface card circuitry, wireless communication circuitry, etc.

Program code may be stored in non-transitory media such as secondary memory 810 or memory 808 or both. In some embodiments, secondary memory 810 can be persistent storage. One or more processors 804 reads program code from one or more non-transitory media and executes the code to enable the computer system to accomplish the methods performed by the embodiments herein, such as those involved with controlling components of stations of a multi-station processing chamber as described herein. Those skilled in the art will understand that the processor may accept source code, such as statements for executing training and/or modelling operations, and interpret or compile the source code into machine code that is understandable at the hardware gate level of the processor. A bus 805 couples the I/O subsystem 802, the processor 804, peripheral devices 806, communication interfaces 807, memory 808, and secondary memory 810.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for providing station-to-station deposition uniformity in a multi-station processing chamber, the method comprising:
obtaining a target deposition thickness for a plurality of substrates each undergoing a deposition process in a corresponding plurality of stations of a multi-station processing chamber, wherein each station of the plurality of stations is operatively coupled to common components associated with the multi-station processing chamber via a plurality of control components that are individually actuated for each station;
obtaining one or more parameters indicating a plurality of deposition rates, each parameter corresponding to a station of the plurality of stations;
determining for each of the plurality of stations, a number of deposition cycles to be performed in association with a corresponding station based at least in part on the one or more parameters indicating a deposition rate of the plurality of deposition rates for the corresponding station and the target deposition thickness, wherein a first number of deposition cycles corresponding to a first station of the plurality of stations is less than a second number of deposition cycles corresponding to a second station of the plurality of stations;
causing the first number of deposition cycles to be performed in connection with each of the plurality of stations by causing a first plurality of control components associated with the first station and a second plurality of control components associated with the second station to each be set to a first position associated with a deposition mode of operation; and
in response to determining that the first number of deposition cycles has been completed:
causing further deposition cycles to be stopped in connection with the first station by causing at least one component of the first plurality of control components associated with the first station to be changed to a second position; and
causing additional deposition cycles to be performed in connection with the second station until the second number of deposition cycles has been completed in connection with the second station by causing the second plurality of control components associated with the second station to remain in the first position associated with the deposition mode of operation until the second number of deposition cycles has been completed and transitioning at least one control component of the second plurality of control components to the second position that causes the stopping of further deposition cycles in response to determining that the second number of deposition cycles has been completed.

2. The method of claim 1, wherein the common components comprise an RF generator.

3. The method of claim 2, wherein the first plurality of control components comprise at least one RF switch that operatively couples the first station to the RF generator.

4. The method of claim 1, wherein the common components comprise at least one gas source.

5. The method of claim 4, wherein the first plurality of control components comprise at least one gas flow valve that operatively couples the first station to the at least one gas source.

6. The method of claim 1, wherein the plurality of deposition rates is obtained via a user interface.

7. A method for providing station-to-station control in a multi-station processing chamber, the method comprising:
obtaining, via a user interface:
a representation of a first time point at which a first plurality of control components associated with a first station of a multi-station processing chamber and a second plurality of control components associated with a second station of the multi-station processing chamber are each to be actuated
to a first position associated with a fabrication process to occur in the first station and the second station, wherein the first plurality of control components operatively couples the first station to common components associated with the multi-station processing chamber and wherein the second plurality of control components operatively couples the second station to the common components associated with the multi-station processing chamber, and
a representation of a second time point at which at least one component of the first plurality of control components is to be actuated to a second position associated with stopping of the fabrication process in the first station and at which the second plurality of control components are to remain in the first position,
causing, at the first time point, the first plurality of control components and the second plurality of control components to each be actuated to the first position; and
causing, at the second time point, the at least one component of the first plurality of control components to be actuated to the second position such that the fabrication process is stopped in the first station while causing the second plurality of control components to remain in the first position such that the fabrication process continues in the second station.

8. The method of claim 7, wherein the fabrication process is one of a deposition process, an etch process, a passivation process, or an inhibition process.

9. The method of claim 7, wherein the representation of the first time point and the representation of the second time point each correspond to a different step of the fabrication process.

10. The method of claim 7, wherein the user interface comprises a plurality of selectable inputs, each corresponding to a state of a control component of the first plurality of control components or the second plurality of control components at a particular step of the fabrication process.

11. The method of claim 7, wherein the user interface comprises a matrix, and wherein elements of the matrix represent states of the first plurality of control components and the second plurality of control components at different steps of the fabrication process.

12. The method of claim 7, wherein the common components comprise an RF generator.

13. The method of claim 12, wherein the first plurality of control components comprise at least one RF switch that operatively couples the first station to the RF generator.

14. The method of claim 7, wherein the common components comprise at least one gas source.

15. The method of claim 14, wherein the first plurality of control components comprise at least one gas flow valve that operatively couples the first station to the at least one gas source.

16. A method for providing station-to-station control in multi-station processing chambers, the method comprising:
identifying:
a first time point at which a first plurality of control components associated with a first station of a multi-station processing chamber and a second plurality of control components associated with a second station of the multi-station processing chamber are each to be actuated to a first position associated with a fabrication process to occur in the first station and the second station, wherein the first plurality of control components operatively couples the first station to common components associated with the multi-station processing chamber and wherein the second plurality of control components operatively couples the second station to the common components associated with the multi-station processing chamber, and
a second time point at which at least one component of the first plurality of control components is to be actuated to a second position associated with stopping of the fabrication process in the first station and at which the second plurality of control components are to remain in the first position,
wherein the fabrication process is an etch process, a passivation process, or an inhibition process;
causing, at the first time point, the first plurality of control components and the second plurality of control components to each be actuated to the first position; and
causing, at the second time point, the at least one component of the first plurality of control components to be actuated to the second position such that the fabrication process is stopped in the first station while causing the second plurality of control components to remain in the first position such that the fabrication process continues in the second station.

17. The method of claim 16, wherein the first time point and the second time point each correspond to a different step of the fabrication process.

18. The method of claim 16, wherein the common components comprise an RF generator.

19. The method of claim 18, wherein the first plurality of control components comprise at least one RF switch that operatively couples the first station to the RF generator.

20. The method of claim 16, wherein the common components comprise at least one gas source.

21. The method of claim 20, wherein the first plurality of control components comprise at least one gas flow valve that operatively couples the first station to the at least one gas source.
